(19) United States
(12) Patent Application Publication
(10) Pub. No.: US 2011/0232723 A1
(43) Pub. Date: Sep. 29, 2011

(54) LAYER SYSTEM FOR SOLAR ABSORBER

(76) Inventor: Dieter Ostermann, Neuss (DE)

(21) Appl. No.: 13/061,184

(22) PCT Filed: Aug. 27, 2009
(86) PCT No.: PCT/EP2009/061056

§ 371 Date: May 11, 2011

(30) Foreign Application Priority Data
Aug. 29, 2008 (DE) 10 2008 044 931.8

(51) Int. Cl. H01L 31/058; F24J 2/24; H01L 31/18; B23P 15/26

(52) U.S. Cl. 136/248; 126/651; 126/677; 29/890.033

(57) ABSTRACT

Solar absorber (1) comprising at least one solar thermal absorber (2) and also at least one solar cell layer system (3) applied thereto and comprising a first layer (10) and a second layer (11) which is directly contact-connected to the first layer (10), wherein the second layer (11) is applied in planar fashion to the solar thermal absorber (2) either directly or indirectly.

The invention relates to a solar absorber, to a solar thermal collector comprising such a solar absorber, and also to a method for the fabrication of such a solar absorber.

Solar-thermal utilization of solar energy that is as efficient as possible has spurred increased development activity in this field in recent years. During this time, numerous concepts have been developed for how solar energy can be made usable for human enterprise under the utilization of basic thermal principles. In addition to numerous developments that are currently either still located in a scientific test stage or else could not become established in large-scale tests, vacuum tube collectors, flat-plate collectors, as well as also parabolic trough collectors. In particular have proven economical in household and also industrial applications. All of these approaches are suitable for converting certain portions of the solar electromagnetic spectrum into thermal energy by special absorber surfaces, with this thermal energy being used to heat a thermal fluid. Such a thermal fluid heated in a solar-thermal system can then be fed, for example, by a circulating pump to a heat exchanger by which the thermal energy stored in the thermal fluid is discharged and made usable in a subsequent step.

The efficiency of such solar thermal systems is determined, in addition to a series of geometric factors, also by basic thermodynamic parameters or material parameters. Such thermal solar systems found in household and also in industrial applications typically achieve an efficiency between 50% and 90%. In contrast, however, 50% to 10% of the solar energy received by the solar thermal system still remains unused and is discharged or emitted again as waste heat.

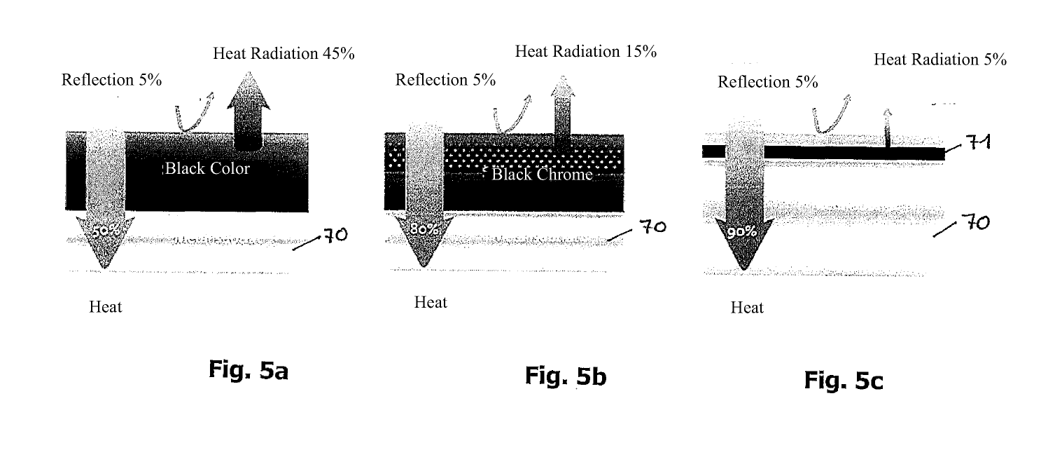

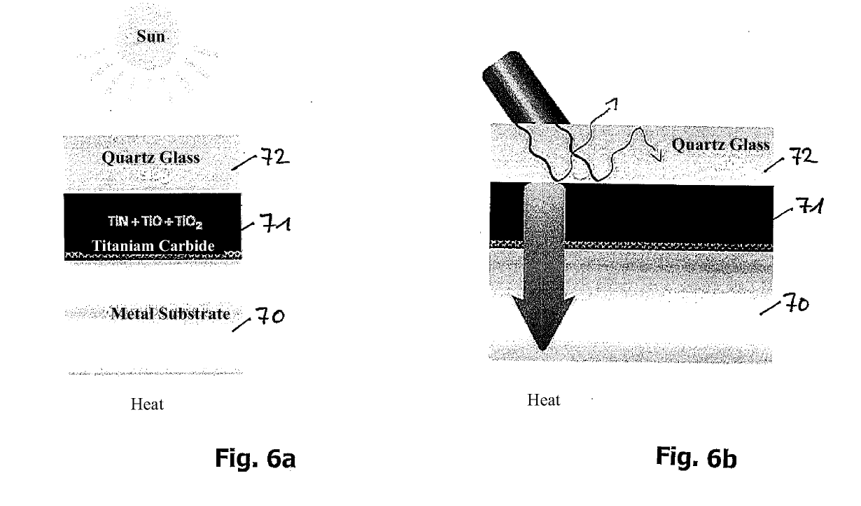

In order to increase the efficiency of the thermal solar systems, numerous improvements of the absorber surfaces have been proposed that are partially realized also in FIGS. 5a, 5b, 5c, 6a, and 6b in detail. Here, the effort has been directed mainly on shaping the absorber surfaces for the solar radiation in an especially selective way, so that the heat loss emission from the absorber surface is reduced. For example, highly selective absorber surfaces are used that provide a multiple coating with quartz glass, a mixture of TiN, TiO, and TiO₂, titanium carbide, on a metallic absorber substrate, and in this way enable the heat losses to be reduced to merely 10%.

In order to increase the total efficiency of a solar system even further, that is, in order to make the received solar radiation usable to a higher percentage, additional technical developments have been proposed that allow a combination of simultaneous thermal and also photovoltaic utilization of the solar radiation.

As representative of such combination systems, reference is made to DE 39 23 821 A1, which proposes the combination of a thermal collector and also a photovoltaic collector in a collector unit. The collector described there provides a thermal fluid system carrying a flow of heat exchanger medium as a component of the thermal collector that is embedded in an insulating aerogel. When solar radiation is incident on the thermal collector, the portions of the solar radiation with shorter wavelength are typically not absorbed and the red or infrared portions are used only after conversion into thermal heat. The photovoltaic collector, which makes usable the rest of the spectrum of the solar radiation, that is, the visible and UV light, for generation of electrical current by the photovoltaic effect, is connected after the thermal collector with respect to the direction of incidence of the solar radiation. The thermal collector and the photovoltaic collector are each separated from the other by a thick layer of insulating aerogel.

The combination shown in DE 39 23 821 A1 of thermal collector and photovoltaic collector has numerous disadvantages due to the structural configuration of the thermal collector and also the geometric arrangement of the thermal collector with respect to the photovoltaic collector. The inclusion of air in the insulating aerogel produces, on one hand, strong scattering of the sunlight incident in the combination collector, whereby a large percentage of solar radiation, especially of infrared radiation, is lost. Furthermore, the scattering cross section is also increased in that the thermal collector provides an arrangement of tubes of the thermal fluid system that is connected before the photovoltaic collector with respect to the direction of incidence of the solar radiation and forms a shadow on this photovoltaic collector. Consequently, a portion of the solar radiation is reflected and diffracted by the tubes of the heat exchanger, so that this portion of radiation can no longer be made available for the generation of photovoltaic current. The efficiency of the photovoltaic current generation is thus significantly reduced. In addition, the structural complexity of the combination collector is also to be mentioned, which causes, on one hand, high fabrication costs, but also significantly increases the susceptibility to faults and the need for maintenance in such systems.

Additional structural efforts with respect to a combination of thermal collector and photovoltaic collector into one unit have also been undertaken, for example by the company Solarhybrid AG. The combination collectors produced by Solarhybrid AG comprise monocrystalline or also polycrystalline solar cells, which are bonded onto the lower side of the cover panes made of glass of a solar thermal collector. Due to this construction, however, the solar cells are very warm when operating under the incidence of radiation and lead to strong reductions of the photovoltaic efficiency. Furthermore, the additional, added solar cells could also unfavorably influence the incidence of light for the thermal heat generation, for example due to shading.

The present invention is therefore based on the object of avoiding the disadvantages described above from the prior art. In particular, the present invention is based on the object of providing a solar absorber that can have a high total efficiency with simultaneous reduction of the fabrication costs in comparison with the solar absorbers known from the prior art.

This object is achieved by a solar absorber according to claim 1, by a solar thermal collector according to claim 16 [13], and also by a method for the fabrication of such a solar absorber according to claim 19 [15].

In particular, the object is achieved by a solar absorber that comprises at least one solar thermal absorber and also at least one solar cell layer system that is deposited on this absorber, wherein this solar cell layer system comprises a first layer and a second layer directly contacted with the first layer, wherein the second layer is deposited over a surface area either directly or indirectly onto the solar thermal absorber.

Furthermore, the object of the invention is achieved by a solar thermal collector that comprises at least one solar absorber described above with at least one solar thermal absorber and at least one solar cell layer system.

Moreover, the object is achieved by a method for the fabrication of a solar absorber with at least one solar thermal absorber and at least one solar cell layer system, wherein the method distinguishes itself by at least the following steps: provision of a solar thermal absorber, deposition of a second layer either directly or indirectly onto the solar thermal absorber, deposition of a first layer directly onto the second layer.

An essential concept of the invention is to be seen in that a solar absorber comprised of a solar thermal collector has a solar thermal absorber and also a solar cell layer system deposited on this absorber. In this way, the solar cell layer system is deposited over a surface area either directly or indirectly onto the solar thermal absorber, so that there is a compact and stable unit made of thermal and photovoltaic collectors. The solar thermal absorber could also be a solar thermal absorber comprised of conventional solar-thermal collectors. Furthermore, the solar thermal absorber could also have a specially conditioned surface that enables not only an improved absorption of solar radiation, but also an improved connection to the solar cell layer system according to the invention.

The solar thermal absorber according to the invention guarantees the conversion of solar radiation, when it is incident on the surface of the solar thermal absorber into heat or heat radiation. In particular, the solar thermal absorber could be especially suitable by surface conditioning or by the application of one or more absorption layers that absorb the red and infrared radiation of the visible portion of the solar spectrum and convert it into heat.

The solar cell layer system according to the invention is connected before the solar thermal absorber with respect to the direction of incidence of the solar radiation. The solar cell layer system enables, for its part, the absorption of the visible and the UV radiation of the solar spectrum, which cannot be converted into heat or heat radiation in a particularly efficient way by the solar thermal absorber. For this purpose, the solar cell layer system can have, on one hand, a suitable transparent area with respect to its transmission, which allows, in particular, the red and the infrared portions of the visible solar spectrum to pass in a largely unhindered way. Due to the planar connection of the solar cell layer system with the solar thermal absorber, the portion of scattering radiation is also greatly reduced, especially when a direct deposition of the solar cell layer system on the solar thermal absorber is provided. Consequently, the portion of the solar radiation entering into the solar cell layer system is made usable either in the solar cell layer system itself through absorption or in the solar thermal absorber through the physical absorption processes taking place there.

The solar cell layer system according to the invention has a first layer and also a second layer contacted directly with the first layer. Here, the first layer could be provided as a photo-anode and the second layer as a photo-cathode of a photovoltaic system. According to the arrangement and selected materials, however, it is also possible that the first layer fulfills the function of a photo-cathode and the second layer fulfills the function of a photo-anode.

As an alternative to a photovoltaic system, the solar cell layer system according to the invention could also represent a photoelectrochemical layer system whose first layer is constructed either as a photo-cathode or photo-anode and whose second layer is constructed accordingly as a photo-anode or photo-cathode. Accordingly, the total efficiency of a solar thermal collector comprising the solar absorber is increased by the additional utilization of solar radiation for the photoelectrochemical generation of gas, in addition to the solar-thermal application. A number of semiconductor materials, for example the groups TiO₂, SrTiO₃, Ge, Si, Cu₂S, GaAs, CdS, MoS₂, CdSeS, Pb₃O₄, or CdSe, are suitable for the construction of the second layer of the solar cell layer system according to the invention. Titanium dioxide (TiO₂) has proven especially suitable, which also can be generated industrially in a relatively economical way. Titanium dioxide can also be used in very different modifications that not only enable a second layer of a different thickness to be manufactured but also the macroscopic layer structure to be selectively influenced. Conceivable here are, for example, ultra-thin TiO₂ layers, TiO₂ films, polycrystalline TiO₂, sintered TiO₂ powder, as well as other TiO₂ crystal structures, as for example, rutile, anatase, or brookite. Furthermore, the semiconductors of the second layer could have a suitable doping that enables a selected adjustment of the energy gaps between the valence band and conduction band.

Furthermore, the first layer directly contacted with the second layer could be formed from a metal or from a semiconductor doped opposite the semiconductor of the second layer. For the manufacture of a semiconductor material of the first layer, the semiconductor materials of the second layer named above could also be included. For the use of a metal for the manufacture of the first layer, care must be taken, in particular, that the surface of the metal is only oxidizable with difficulty, that is, has a relatively large work function, in order to prevent degradation of the layer during operation. For the manufacture of the first layer, the elements Ru, Rh, Pd, Ag, Os, Ir, Pt, Au, Al, Cr, Cu, Ni, Mo, Pd, Ta, and W are especially suitable.

According to the material being used for the first layer, either a pn junction is formed between the first layer and the second layer (in the case of the use of a semiconductor material) or else a Schottky contact is formed (this could be the case with the use of a metal).

For suitable selection of the materials of the first layer and also the second layer of the solar cell layer system, on one hand a suitable photovoltaic system could be manufactured that has sufficient transparency in order to allow the portions to pass that are important for the solar-thermal utilization of the solar radiation. Furthermore, a suitable selection of materials for the first layer and also the second layer also allows a suitable photoelectrochemical system to be manufactured, which is likewise transparent for the portions that are used for the solar-thermal heat generation. If the solar absorber according to the invention is used for the simultaneous generation of solar-thermal heat and also for photoelectrochemical gas generation, it requires an electrolyte that surrounds or washes around the solar cell layer system. With respect to the principles of photoelectrochemical gas generation, refer to DE 10 2004 012 303.

Furthermore, another essential concept of the present invention is to be seen in that the direct or indirect deposition of the solar cell layer system on the solar thermal absorber allows a suitable cooling of the solar cell layer system. This is also aided in that the thickness of the solar cell layer system is relatively small in comparison with the expansions of the entire solar thermal absorber and has only a low thermal capacity. In particular, for the operation of the solar cell layer system as a photovoltaic system, a large portion of heat radiation or heat energy is produced that can lead, under typical conditions of use, to large efficiency losses in the photovoltaic current generation. Typically, the efficiency of the photovoltaic current generation decreases, namely, by approximately 0.5% with each additional ° Celsius. In this respect, sufficient cooling of the solar cell layer system is extremely important for improving the photovoltaic efficiency.

Due to the direct or indirect deposition of the solar cell layer system onto the solar thermal absorber, according to the invention an efficient heat dissipation can now also be realized from the solar cell layer system via the solar thermal absorber. Because a solar thermal absorber in the solar thermal collector typically dissipates the usable heat generated by absorption of the solar radiation to a thermal fluid system, the heat generated in the solar cell layer system could also be discharged simultaneously and effectively to this thermal fluid system. Thus, on one hand, the solar thermal yield or the solar thermal efficiency is increased and, on the other hand, the photovoltaic current yield or the photovoltaic efficiency is improved.

Furthermore, the direct or indirect deposition of the solar cell layer system according to the invention onto the solar thermal absorber reduces a shading of the solar thermal absorber, whereby the solar thermal efficiency could be reduced. In particular, according to the invention, no mounts/adhesive layers or devices are provided that create the connection of solar thermal absorber and solar cell layer system. Because such mechanical elements lead to the reduction of the solar thermal efficiency due to shading and light reflection or light scattering, the arrangement of the solar cell layer system on the solar thermal absorber according to the invention produces an essentially non-reduced solar thermal light yield. This is also supported in that the solar cell layer system could have a very thin construction.

In a first embodiment of the solar absorber according to the invention, it is provided that the solar cell layer system is transparent at least for a portion of the solar light spectrum, in particular for a red and/or infrared portion of the solar light spectrum. In this way, the wavelength ranges of the solar light spectrum that are especially important for a solar thermal application could be incident on the solar thermal absorber and allow a conversion of the electromagnetic light energy into heat. Furthermore, the spectral ranges that are important in the visible and also the UV range of the light spectrum for a photovoltaic current generation or for a photoelectrochemical conversion are made available to the solar cell layer system. Moreover, by suitable selection of the materials for the first and second layer of the solar cell layer system and also by the suitable selection of the thicknesses of these layers, an advantageous influence of the transmission response of the solar cell layer system can be achieved.

In another embodiment of the solar absorber according to the invention, the solar cell layer system has a thickness of not more than 1000 nm, in particular not more than 750 nm, preferably between 400 nm and 600 nm, and more preferably approximately 500 nm. The selection of the thickness of the solar cell layer system according to this embodiment allows a sufficient transmission of the solar radiation that is provided for the solar thermal conversion by absorption by the solar thermal absorber, whereby the solar cell layer system also allows sufficient radiation of the non-transmitted radiation portions into the solar cell layer system for charge separation. Moreover, the quantities of material to be applied and thus the resulting material costs due to the very low thickness of the entire solar cell layer system are relatively low and thus economical.

In another construction, it could be provided that the first layer of the solar cell layer system comprises platinum and the second layer comprises titanium dioxide. In particular, due to the low fabrication costs for titanium dioxide and the high standard potential (work function) of platinum (+1.2 volts), these two materials are especially suitable for generating a solar cell layer system. Furthermore, the first layer made of platinum can be deposited in an especially advantageous way on a layer made of titanium dioxide by, for example, vacuum deposition.

In a further embodiment, the second layer that comprises titanium dioxide could have an n-doping or a p-doping. According to an n-doping, the second layer that comprises titanium dioxide would construct a photo-anode when irradiated with solar electromagnetic energy, on whose surface, in particular, a photoelectrochemical oxidation of a reducing agent occurring in an electrolyte solution takes place. In the alternative case of a p-doping of the second layer, this could form a photo-cathode, whereby a reduction of an oxidation agent occurring in the electrolyte solution takes place on its surface.

In another embodiment of the solar absorber according to the invention, the first layer has recesses, in particular trenches, which open up predetermined areas of the second layer. In particular, for the photoelectrochemical generation of a gas during decomposition of an electrolyte solution it is required that both the photo-anode and also photo-cathode are in contact with the electrolyte solution for charge carrier balancing. Consequently, by the recesses provided in the first layer, a portion of the electrolyte solution could come into contact with the second layer, whereby on the surface of the second layer exposed there, either an oxidation or reduction can take place, depending on the construction of the solar cell layer system.

In another embodiment of the solar absorber according to the invention, the solar thermal absorber contains copper and/or aluminum. Both materials have suitable surface structures, in order to guarantee a durable and uniform deposition of the solar cell layer system. In addition, both materials are good heat conductors that can efficiently conduct or discharge the heat generated in a solar thermal way.

In a preferred, further embodiment of the solar absorber according to the invention, the solar cell layer system comprises a third layer, in particular made of titanium that is provided in direct contact with the second layer on the side of the second layer opposite the first layer. This third layer allows, on one hand, an advantageous electrical contacting of the second layer and also represents a stable, conductive substrate. In particular, an ohmic resistance that determines the electrical conduction response within the solar cell layer system is constructed between the third layer of the solar cell layer system and the second layer of the solar cell layer system.

According to another embodiment of the solar absorber according to the invention, the solar cell layer system comprises a fourth layer, in particular an insulation material, which is provided in direct contact with the second layer or in direct contact with the third layer on the side of the second layer facing away from the first layer. The fourth layer is used in an especially advantageous way for the electrical insulation of the solar cell layer system with respect to the solar thermal absorber, so that no charges generated in the solar cell layer system could flow out electrically via the solar thermal absorber. The fourth layer can be constructed here in an especially preferred way as a silicon dioxide layer that can be easily deposited on the solar thermal absorber, for example by suitable dipping processes or sol-gel processes, for example with the use of tetraethyl orthosilicate (TEOS).

In an advantageous embodiment of the solar absorber according to the invention, the first layer has a thickness of not more than 25 nm, in particular not more than 18 nm, preferably between 8 nm and 15 nm, and more preferably approximately 13 nm. In a preferred, currently pursued embodiment, the thickness of the first layer equals 13 nm.

In another embodiment of the solar absorber according to the invention, the second layer has a thickness of not more than 650 nm, preferably between 450 nm and 550 nm, and more preferably approximately 500 nm. In a preferred, currently pursued embodiment, the thickness of the second layer equals 500 nm.

In another embodiment of the solar absorber according to the invention, the second layer comprises a plurality of individual particles, which have an average diameter of not more than 50 nm, in particular not more than 35 nm, preferably between 15 nm and 25 nm, and more preferably approximately 20 nm. Advantageously, the plurality of individual particles of the second layer is arranged as a cluster compound. In this way, a nanostructured layer of the solar cell layer system can be manufactured that allows, on one hand, the surfaces to be increased and allows, on the other hand, additional energy states to be created within the typically forbidden zone of the material of the second layer, which expands the usable wavelength range especially toward lower energy states. In an alternative embodiment, the first layer of the solar cell layer system could also be formed as a plurality of individual particles or clusters.

In another embodiment of the solar absorber according to the invention, the third layer has a thickness of 5 nm to 25 nm. The third layer must be constructed as thin as possible due to the desired transparency and is, in this respect, preferably 5 nm to 25 nm.

In addition, it could be provided that the solar absorber according to the invention distinguishes itself in that the solar thermal absorber comprised by it has a plurality of solar cell layer systems, which are connected electrically in series to each other. In particular, for use as a photovoltaic system, the voltage of the individual solar cell layer systems could be summed, resulting in an elevated output voltage.

In another embodiment of the solar absorber according to the invention, the solar thermal absorber is provided for use in a conventional solar thermal collector. Accordingly, conventional or industrially typical solar thermal collectors can be retrofitted very economically by use of one or more solar absorbers according to the invention, whereby the housing of the solar thermal collector can be left essentially unchanged. In the case of the use of the solar cell layer system as a photovoltaic system, only at least one electrical line feedthrough is required in the housing of the solar thermal collector. In the case of the use of the solar cell layer system in the sense of a photoelectrochemical system, the housing of the solar thermal collector is to be expanded to the extent that this can be filled at least partially with an electrolyte solution by one or more inlets, whereby spent electrolyte can be removed from the housing of the solar thermal collector via an outlet and the electrolytically generated gases can be discharged from the housing of the solar thermal collector simultaneously via this same outlet or via an additionally provided outlet.

In an especially preferred embodiment of the solar thermal collector according to the invention, the solar cell layer system could be wired electrically in a way that is suitable for the photovoltaic current generation, wherein the solar thermal absorber is coupled with a thermal fluid system suitable for the simultaneous solar thermal energy production. Accordingly, during operation, that is, when irradiated with solar electromagnetic radiation, photovoltaic, electrical current can be generated simultaneously and the heat discharged via the thermal fluid system can be made usable, for example, by a heat exchanger.

In an alternative embodiment of the solar thermal collector according to the invention, the solar thermal collector has at least one inlet for an electrolyte solution, in particular of water, and also an outlet for gas, whereby the solar cell layer system is suitable for photoelectrochemical gas generation, and wherein the solar thermal absorber is coupled with a thermal fluid system suitable for simultaneous solar thermal energy production. Accordingly, the solar thermal collector according to this embodiment could be used for the simultaneous generation of gas manufactured in a photoelectrochemical way and heat generated in a solar-thermal way. The gas manufactured in a photoelectrochemical way, in the case of use of water as the electrolyte solution, is a mixture made of hydrogen and oxygen. After discharge of the gas mixture from the solar thermal collector, this could be separated according to technically common methods. For the use of a solar cell layer system made of platinum and n-doped titanium dioxide, this leads to an oxidation of the water molecules on the surface of the second layer and also to a reduction of positively charged hydrogen ions on the surface of the first layer. In a further embodiment, a solar thermal collector is also conceivable that is simultaneously suitable for photovoltaic current generation, for photoelectrochemical gas generation, and also for thermal heat generation.

According to a preferred embodiment of the method according to the invention for the fabrication of a solar absorber, the deposition of the first and/or the second layer is carried out by a gel-coating process, in particular, by a sol-gel process, by spray coating, by dip coating, by CVD, by PVD, or by sputtering. All of the mentioned methods allow the deposition of a resistant and durable layer in a way that is economically and technically simple to realize.

Additional embodiments of the invention are given in the dependent claims.

Below, the invention will be described with reference to embodiments that will be explained in detail with reference to the figures.

Shown herein are:

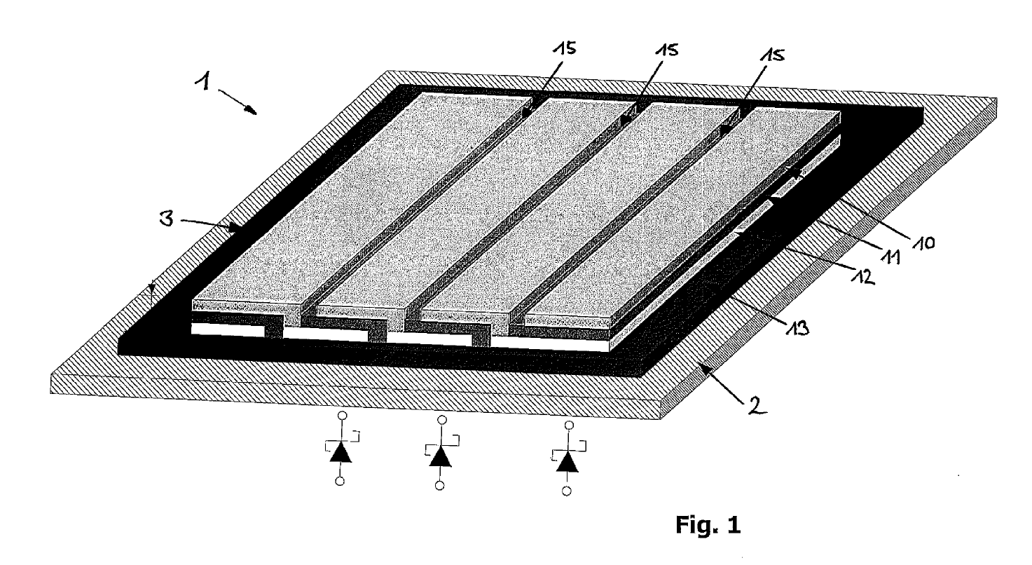

FIG. 1 a perspective oblique view of a first embodiment of the solar absorber according to the invention, comprising a solar thermal absorber together with a solar cell layer system,

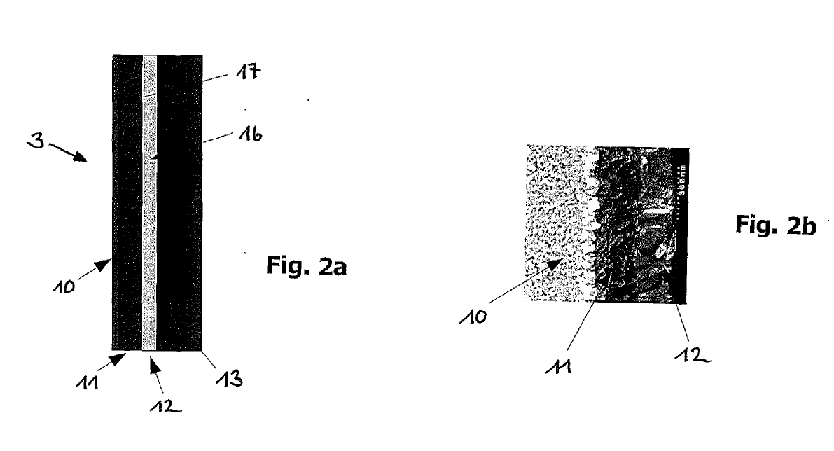

FIG. 2a a cross-sectional view through another embodiment of the solar cell layer system according to the invention,

FIG. 2b a micrograph of a polished cut through an embodiment of the solar cell layer system according to the invention,

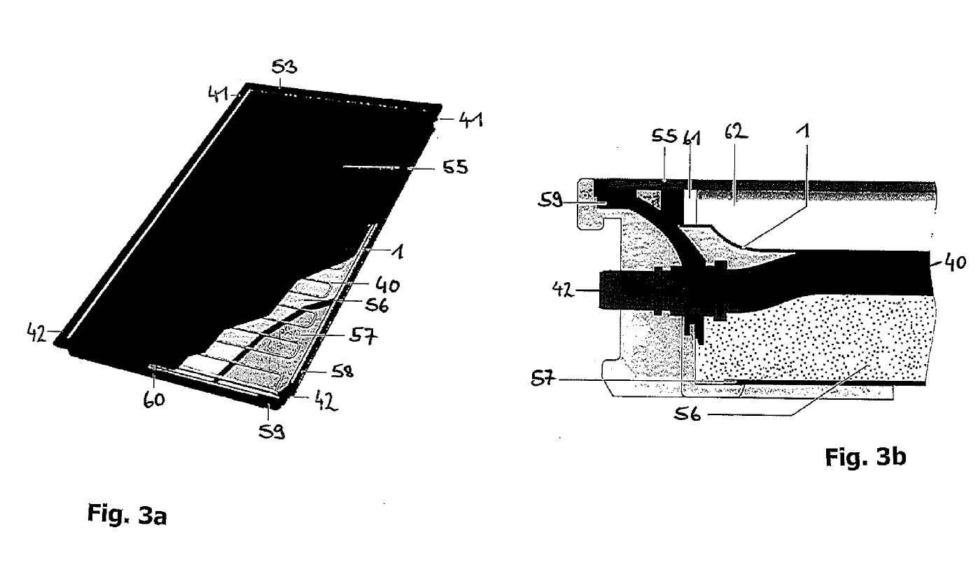

FIG. 3a a perspective partial section view through a solar thermal collector equipped with an embodiment of a solar absorber according to the invention for the simultaneous generation of solar thermal heat and photovoltaic current,

FIG. 3b a side section view through the solar thermal collector according to FIG. 3a,

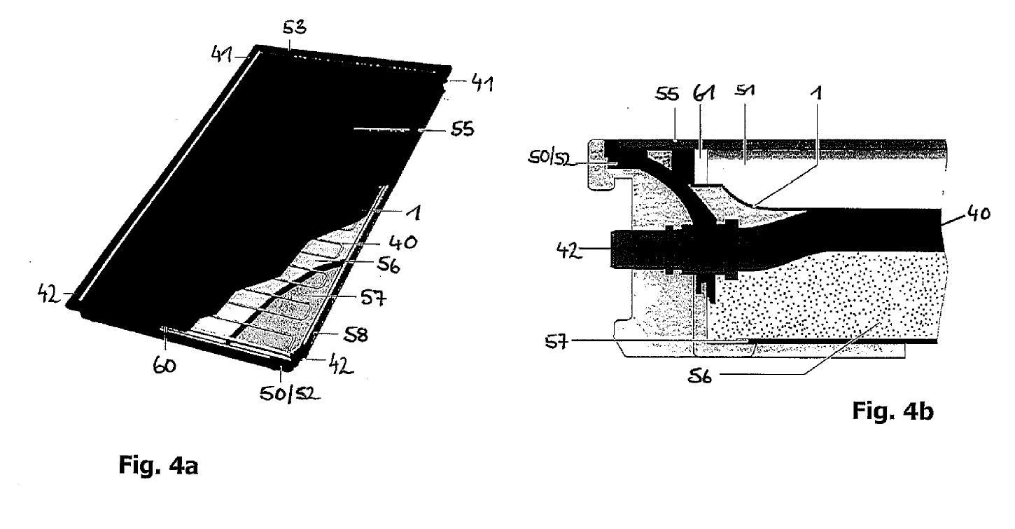

FIG. 4a a perspective partial section view through a solar thermal collector equipped with an embodiment of a solar absorber according to the invention for the simultaneous generation of solar thermal heat and the photoelectrochemical generation of gas,

FIG. 4b a side section view through a solar thermal collector according to FIG. 4a,

FIG. 5a a schematic diagram of the solar thermal energy flows in a conventionally coated solar thermal absorber,

FIG. 5b a schematic diagram of the solar thermal energy flows in a solar thermal absorber coated with black chrome,

FIG. 5c a schematic diagram of the solar thermal energy flows in a solar thermal absorber coated with a highly selective coating,

FIG. 6a a schematic side section view through the solar thermal absorber shown in FIG. 5c and coated with a highly selective coating,

FIG. 6b a schematic partial diagram of the energy flows in the solar thermal absorber shown in FIG. 6a and coated with a highly selective coating.

In the following, identical reference symbols are used for all of the components and features that are the same or have the same actions.

FIG. 1 shows a perspective diagram of a first embodiment of a solar absorber 1 according to the invention that comprises a solar thermal absorber 2 and also a solar cell layer system 3 deposited on this absorber. The shown solar thermal absorber 2 is a metal layer that has a planar construction and can be made, for example, of copper or aluminum or at least comprises these metals in the form of an alloy. On the surface of this metallic solar thermal absorber 2, initially a fourth layer 13 is deposited that is, as a single coherent layer, in direct contact with the surface of the solar thermal absorber 2. On the side of the fourth layer 13 facing away from the solar thermal absorber 2, four third layers 12 oriented parallel to each other and spaced apart from each other with equal spacing are deposited in the form of strips. On the surfaces of each of the third layers 12 facing away from the fourth layer 13 there is, in turn, a second layer 11 deposited in strip form, which also fills up the intermediate space between two adjacent and spaced-apart third layers 12 in a step-shaped arrangement. On the surfaces of each of the second layers 11, which are facing away from each of the third layers 12 there are first layers 10 arranged in strip form that fill up, in turn, the areas between two adjacent second layers 11 in step-shaped arrangement. Both the first layers 10 and also the second layers 11 and also the third layers 13 have a parallel arrangement relative to each other, wherein the layers arranged adjacent to each other in strip form have a uniform spacing. According to this arrangement, a recess 15 that opens up the surface to each second layer 11 is provided between each of the first layers 10 arranged adjacent to each other and oriented in parallel.

Such an arrangement of the individual layers relative to each other is advantageous, especially when the shown solar absorber is used for solar thermal energy production and also for simultaneous photoelectrochemical gas production. For this purpose, the solar cell layer system 3 comprising the first layers 10, the second layers 11, the third layers 12, and the fourth layer 13 is washed partially around with an electrolyte solution, whereby the recesses 15, which are constructed in the present case as trenches, are filled by this electrolyte solution. When the solar absorber 1 according to this embodiment is irradiated with light energy, in particular with solar light energy, this results in a decomposition of the electrolyte solution or individual components of this electrolyte solution on the surfaces of the first layers 10 and also the surfaces of the second layers 11 exposed in the recesses 15.

In a preferred embodiment, the fourth layer 13 is constructed as an insulation layer, which is made in an especially preferred way from an electrically insulating layer made of silicon dioxide. Such a layer could be manufactured, for example, on the surface of the solar thermal absorber 2 by a dip coating method, especially by a sol-gel method. According to this embodiment, the third layers 12 are constructed as metallic titanium layers. In particular, CVD, PVD, or sputtering methods are suitable for the deposition of these layers on the fourth layer 13. The second layers 11 deposited on the third layers 12 are made of titanium dioxide according to the embodiment and could be deposited by comparable methods. The terminal first layers 10 are deposited, for their part, in another processing step that can operate essentially according to the method useable for the deposition of the third layers 12. Here, the first layers 10 are made of platinum according to the embodiment.

If the second layers 11 made of titanium dioxide now have an n-doping, then a number of hole-electron pairs is generated in these layers when light is incident on them, whereby the released electrons migrate to the first layers 10, in order to drive a reduction reaction there. The remaining holes accumulate at the surface in the second layers 11 and oxidize additional electrolyte components in the exposed areas of the recesses 15. If the electrolyte solution involves water, then this oxidation leads to the production of oxygen and also the reduction on the surfaces of the first layers 10 made of platinum to hydrogen. Here, the junction between the first layers 10 and second layers 11 attached to each other over a surface area acts in the sense of a Schottky diode which has no pn junction, that is, semiconductor-semiconductor junction, but instead a metal-semiconductor junction. Like a diode with a pn junction, however, a Schottky diode also has rectifying characteristics. Symbolically, the Schottky diodes represented by the corresponding layer arrangements are reproduced by the standard switch symbols in the lower region of the diagram. According to this embodiment, the corresponding layers 10, 11, and 12 have a strip width of ca. 20 mm.

The total thickness of the layer system made of the first layers 10, the second layers 11, and the third layers 12 equals ca. 560 nm according to this embodiment.

FIG. 2a shows a section view through another embodiment of the solar cell layer system according to the invention made of a fourth layer 13, a third layer 12, a second layer 11, and a first layer 10. Comparable with the embodiment shown in FIG. 1, the shown fourth layer 13 is provided for electrical insulation, wherein the third layer 12 represents a 400 nm thick titanium layer, the second layer 11 an approximately 150 nm thick n-doped titanium dioxide layer, and also the first layer 10 a ca. 10 nm thick platinum layer. Here, during operation, when irradiated with solar radiation an ohmic contact 16 forms between the third layer 12 and the second layer 11. The Schottky contact 17, which is important for the photovoltaic and also for the photoelectrochemical function of the illustrated solar cell layer system 3, is constructed in a junction region between the second layer 11 and the first layer 10.

FIG. 2b shows a scanning tunneling electron microscope micrograph of a section and a cross-section polish through an embodiment of the solar cell layer system according to the invention. In particular, the elementary third layer 12 made of titanium is shown there, which is present in direct contact with the second layer 11 made of the n-doped titanium dioxide. The second layer 11 is located, for its part, in direct contact with the first layer 10 made of platinum. In order to simplify the graphical reproduction, the illustrated layer thicknesses were adjusted to be disproportionately large in comparison with the layer thicknesses shown in FIG. 2a.

FIG. 3a shows a perspective partial section diagram through an embodiment of a solar thermal collector according to the invention. This could be realized in the sense of a modification of a conventional solar thermal collector (in the present case, the Buderus SKS 4.0 high-performance collector is shown) by incorporating an embodiment of the solar absorber according to the invention. By this retrofitting, the costs for the performed reconfiguration are significantly reduced in comparison with the fabrication of a new system. Here, the thermal fluid system 40, which has thermal fluid inlets 41 and thermal fluid outlets 42, requires no additional adjustments.

Instead, the thermal fluid system 40, constructed in the present case as a double meander, can be kept unchanged. For adaptation of the solar thermal collector, it requires only the insertion of a solar absorber 1 according to one embodiment of the present invention. For the discharge of the photovoltaically produced current, it further requires suitable electrical wiring, which can be led out of the housing via the electrical line feedthrough 59. The line feedthrough 59 could be provided in the frame 58 produced from fiberglass in a corner region, which is produced using plastic injection-molded technology for reinforcement. Furthermore, the solar thermal collector shown in the present case comprises a glass cover 55, which is constructed, for example, as a 3.2 mm thick single-wafer safety-glass cover. For thermal heat insulation, a layer of insulation material 56 could be provided, which is arranged between the thermal fluid system 40 and a back wall 57. According to this embodiment, the back wall could be a 0.6 mm thick aluminum-zinc-coated steel plate and the insulation material could be a layer of 55 mm thickness of outgassing-free insulation material. Like the conventional solar thermal collector, the solar thermal collector according to this embodiment also has a probe immersion sleeve 53 in the vicinity of an edge compound 60.

FIG. 3b shows a side section view through the solar thermal collector shown in FIG. 3a in the region of the electrical line feedthrough 59. In particular, the glass cover 55 can be recognized there, wherein this glass cover defines, together with a seal 61 and also the surface of the solar absorber 1, a hollow space that is filled with a filling gas 62, in particular noble gas, for reasons of reduced heat conduction. The solar absorber 1 is located in direct contact with the thermal fluid system 40, so that for the solar thermal heat generation, the heat generated in the solar absorber 1 can be discharged directly to the thermal fluid system 40. The thermal fluid [system] 40 here carries a flow of thermal fluid, which is discharged via the thermal fluid outlet 42 from the solar thermal collector. For improving the thermal efficiency, the insulation material 56 is arranged between the back wall 57 and the thermal fluid system 40, whereby this insulation material is to prevent loss emission and dissipation of heat toward the back side of the solar thermal collector.

The solar thermal collector shown in FIG. 4a is essentially the same as the solar thermal collector shown in FIG. 3a, wherein the solar thermal collector shown in FIG. 4a is not constructed as a combined photovoltaic, solar thermal fluid, but instead as a combined thermal and photoelectrochemical solar thermal collector.

In comparison with the configuration of the solar thermal collector shown in FIG. 3a, the solar thermal collector according to FIG. 4a comprises a solar absorber 1, which is equipped, in addition to the solar thermal absorber 2 (not shown in the present case), with a solar cell layer system 3 (not shown in the present case) that is suitable for photoelectrochemical applications. Instead of an electrical line feedthrough 59 in FIG. 3a, the solar thermal collector shown in FIG. 4a was equipped with an inlet 50 and also an outlet 52, which allow an electrolyte solution 51 (not shown in the present case) to be inserted into the solar thermal collector. The gas shown in the scope of the use or the photoelectrochemical decomposition of the electrolyte solution could be removed either via openings not shown further or else also via the outlet 52 together with the spent electrolyte solution.

FIG. 4b represents, in a side section view, the area of the solar thermal collector in FIG. 4a reconfigured in the present case comparable to FIG. 3b. In addition to the inlet 50 and outlet 52 (not shown in detail) for the electrolyte solution 51, the detail shown in FIG. 4b differs from the detail shown in FIG. 3b only in that the filling gas 62 of FIG. 3b is replaced by the electrolyte solution 51.

FIG. 5a represents a schematic side view through a conventionally coated solar thermal absorber. In the simplest embodiment shown in FIG. 5a, the surface of the solar thermal absorber made of metal 70 is coated with a black color. Such solar thermal absorbers allow the conversion of approximately 50% of the solar radiation into heat and can be made usable for solar heat. 5% of the solar radiation is here typically reflected on the surface of the deposited black color, whereas 45% of the heat shown in the solar thermal absorber is dissipated back to the environment in unused form.

In comparison, a coating with black chrome of the metal substrate surrounded by the solar thermal absorber here exhibits a significant energy efficiency increase. With use of a black chrome coating which, however, is very environmentally unfriendly, typically 80% of the solar radiation is absorbed for use by the solar thermal absorber, while only 5% is reflected and 15% of the generated heat is dissipated as heat radiation back to the environment in unused form.

With the use of highly selective coatings, however, it is possible to even further increase the efficiency of conventional solar thermal absorbers. Such highly selective coatings 71 allow, for example, the thermal utilization of 90% of the solar radiation, whereas only 5% is lost by reflection of the solar radiation at the highly selective coating 71 and approximately 5%, in turn, of the energy absorbed by the solar thermal absorber is dissipated back to the environment as heat radiation.

An exemplary embodiment of the highly selective coating 71 presented in FIG. 5c is shown in FIG. 6a in a cross-sectional diagram. Here, the highly selective coating 71 is protected by a cover layer made of quartz glass (SiO₂) 72 as protective layer and anti-reflection layer. The thickness of this layer typically equals 0.1 μm. Between the layer made of quartz glass 72 and the metal 70 (metal substrate) there is the highly selective absorber layer 71 arranged together with a diffusion barrier. The highly selective absorber layer typically comprises a mixture made of TiN, TiO, and also TiO₂ and has a thickness of approximately 0.1 μm. The similarly provided diffusion barrier could be made of titanium carbide. Due to this coating, advantageously more light of the blue spectral range of the solar spectrum is reflected at the boundary layer between the layer on the quartz glass 72 and the highly selective absorber layer 71, whereby, in particular, the infrared portions of the solar spectrum are absorbed by the solar thermal absorber in the form of heat. This situation is shown schematically in FIG. 6b.

At this point, it should be noted that all of the parts described above are claimed as essential to the invention viewed alone and in any combination, especially the details shown in the drawings. Modifications from these parts are familiar to someone skilled in the art.

### REFERENCE SYMBOLS

1 Solar absorber
2 Solar thermal absorber
3 Solar cell layer system
10 First layer
11 Second layer
12 Third layer
13 Fourth layer/insulation material
15 Recesses/trenches
16 Ohmic contact
17 Schottky contact
20 Particle
30 Solar thermal collector
40 Thermal fluid system
41 Thermal fluid inlet
42 Thermal fluid outlet
50 Inlet (electrolyte solution)
51 Electrolyte solution
52 Outlet (electrolyte solution)
53 Probe immersion sleeve
55 Glass cover
56 Insulation material
57 Back wall
58 Frame
59 Electrical line feedthrough
60 Edge compound
61 Seal
62 Filling gas
70 Metal
71 Highly selective coating
72 Quartz glass

1.-16. (canceled)

17. A solar absorber (1) comprising at least one solar thermal absorber (2) and also at least one solar cell layer system (3), which is deposited on the solar thermal absorber and comprises a first layer (10) and a second layer (11) contacted directly to the first layer (10), wherein the second layer (11) is deposited over a surface area either directly or indirectly onto the solar thermal absorber (2).

18. The solar absorber according to claim 17, wherein the solar cell layer system (3) is transparent at least for one portion of the solar light spectrum, in particular for a red and/or infrared portion of the solar light spectrum.

19. The solar absorber according to claim 17, wherein the solar cell layer system (3) has a thickness of not more than 1000 nm.

20. The solar absorber according to claim 17, wherein the first layer (10) of the solar cell layer system (3) comprises a noble metal and the second layer (11) comprises titanium dioxide.

21. The solar absorber according to claim 17, wherein the first layer (10) has recesses (15) which open up predetermined areas of the second layer.

22. The solar absorber according to claim 17, wherein the solar cell layer system (3) comprises a third layer (12) which is provided in direct contact with the second layer (11) on the side of the second layer (11) lying opposite the first layer (10).

23. The solar absorber according to claim 22, wherein the solar cell layer system (3) comprises an insulative fourth layer (13) which is provided in direct contact with the second layer (11) or in direct contact with the third layer (12) on the side of the second layer (11) facing away from the first layer (10).

24. The solar absorber according to claim 17, wherein the first layer (10) has a thickness of not more than 25 nm.

25. The solar absorber according to claim 17, wherein the second layer (11) has a thickness of not more than 650 nm.

26. The solar absorber according to claim 17, wherein the second layer (11) comprises a plurality of individual particles (20), which have an average diameter of not more than 50 nm.

27. The solar absorber according to claim 22, wherein the third layer (12) has a thickness of 5 nm to 25 nm.

28. The solar absorber according to claim 17, wherein the solar thermal absorber (2) has a plurality of solar cell layer systems (3), which are connected electrically in series to each other.

29. A solar thermal collector, comprising at least one solar absorber (1) with at least one solar thermal absorber (2) and at least one solar cell layer system (3) according to claim 17.

30. The Solar thermal collector according to claim 29, wherein the solar thermal collector (30) has at least one inlet (50) for an electrolyte solution (51), and also an outlet (52) for gas, wherein the solar cell layer system (3) is suitable for photoelectrochemical gas generation, and wherein the solar thermal absorber (2) is suitably coupled with a thermal fluid system (40) for simultaneous solar thermal energy production.

31. A method for the fabrication of a solar absorber (1) according to claim 17 with at least one solar thermal absorber (2) and at least one solar cell layer system (3), the method comprising:
provision of a solar thermal absorber (2),
deposition of a second layer (11) either directly or indirectly on the solar thermal absorber (2), and
deposition of a first layer (10) directly on the second layer (11).

32. The method for the fabrication of a solar absorber according to claim 31, wherein the deposition of the first (10) and/or the second layer (11) is carried out by a gel coating process, by spray coating, by dip coating, by CVD, by PVD, or by sputtering.
